(19) United States
(12) Patent Application Publication
(10) Pub. No.: US 2012/0258407 A1
(43) Pub. Date: Oct. 11, 2012

(54) Multifield incoherent Lithography, Nomarski Lithography and multifield incoherent Imaging

(76) Inventor: Gabriel Y. Sirat, Paris (FR)

(21) Appl. No.: 13/506,325

(22) Filed: Apr. 12, 2006

Related U.S. Application Data
(60) Provisional application No. 60/670,272, filed on Apr. 12, 2005.

(51) Int. Cl. G03F 7/20; G02B 5/30; G06F 17/50

(52) U.S. Cl. 430/322; 716/52; 359/483.01

(57) ABSTRACT

A new optical method and apparatus, applicable to optical lithography, to imaging or to machine vision, including:
a mask,
a first optical component, the splitter creating coherent fully registered duplicates, propagating as independent fields, in different optical states,
a physical operator applied on each field concurrently and different for each field,
a combiner to recombine the fields into coherent superposition of the fields, the multifield aerial image.

The method provides the capacity to modify the multifield aerial image by changing the energy ratio between the fields, creating a shape variation of the multifield aerial image. The method provides also the capacity to perform the modification dynamically following a given predetermined functionality.

This application is a continuation of a provisional application, No. 60/670,272, named “Nomarski lithography: A New Approach to SubWavelength Lithography” on the 12 Apr. 2005 and a second provisional application named: “Nomarski lithography: A New Approach to SubWavelength Lithography, Second part: Resolution tripling, longitudinally displaced Nomarski Lithography and Conoscopic Lithography” on the 2 Sep. 2005 both applied for by Gabriel Y Sirat.

The present invention relates generally to optical lithography. It is aimed to develop a new approach to optical Lithography enabling the creation of more complex and more resolved light distributions, with improved functional parameters, using simpler and lower cost masks.

One of the critical steps of the lithographic process is the creation of an aerial image with suitable resolution and quality. The standard lithographic process uses a mask with smaller and smaller features, imaged through an adapted lithographic system. Indeed, Moore law has stretched the mask technologies to a high level of complexity. The mask has become one of the most complex and expensive parts of the lithographic system [1, 2]. The ITRS [3] has defined the development of cost-effective optical and post-optical masks as one of the five difficult challenges for near (through 2009) and medium (above 2010) periods.

The lithographic process in its earliest days was based on a photographic paradigm. The aerial image was a scaled down, accurate, representation of the mask pattern. The introduction, by Levenson, [4], of the phase-shift mask was the first step outside of this concept. The next step was the development of RET, in which the mask pattern is modified and deformed. Finally the emergence of mathematical techniques based on an inverse problem mathematical framework, in which the final image is not used as the starting point of the procedure, [5], have created a stronger and stronger dissimilarity between the mask and the aerial image created on the wafer [6-9].

Recognizing this evolution, a major effort is being pursued in the lithographic industry in order to be able to invert mathematically the aerial image, i.e. to calculate the mask, the coherence factor and the illumination which will create a given aerial image, necessary to realize a given IC design. The optimization algorithm calculates the mask and adjusts the coherence factor and the illumination parameters to create the aerial image. It is currently accepted that this procedure, coupled with immersion lithography, will be sufficient for the 90 nm and 65 nm and may even permit to reach the 45 nm node.

This patent is a continuation of the said strategy; it is indeed astonishing to see the huge improvements, which have been obtained using adapted optimization of the coherence factor, illumination shape and mask design parameters. However, an optimization algorithm is as good as the range of parameters he spans. By opening a new domain of parameters, related to the light distribution, orthogonal to the mask shape parameters, this patent opens the way to either improve even further the aerial image complexity, improve the functional parameters—the exposure window—or decrease the mask complexity and its cost.

It has to be kept in mind that the existing technologies create an inherent constraint in lithography, the binarity of the mask. Even the addition of a negative value, using phase masks, with a large additional cost, leaves the initial mask far from the theoretical gray levels mask. This constraint creates a major mathematical complexity, which can be only partially solved by adequate algorithmic. The solutions, in any case, will add to the mask complexity and cost or reduce the process window. Obviously, a grey level mask will have permit additional performances and a simpler optimization process, but is not realizable using the current lithographic systems.

In this patent we go one step further, in the direction of a grey level mask, using the existing lithographic systems with an adequate modification. The final aerial image will be identical to the aerial image created by a grey level mask—the equivalent mask described later. The equivalent mask is not an arbitrary grey level mask and is limited by an additional set of constraints—but it spans a much larger domain of solutions then the binary—or phase—masks.

In the following paragraphs I will first define part of the terminology used in this patent.

Single field lithography refers to the simple lithographic set-up in which a light distribution is created by the mask and its image is applied, as a light intensity, on the wafer. This is the standard well-known system in lithography.

Multiple exposure lithography, refer to the sequential exposure of two—or more—light distributions. These light distributions add as intensities. Several such systems are in development, in most cases using different masks and in some cases using the same mask.

Multifield aerial image is a term I use, to describe a lithography process using the coherent superposition of two—or more—fields. It is differentiated from single field lithography and from multiple exposure lithography. Multifield aerial image systems proposed up to now where always based on coherent lithography. In the prior art, it had been implemented using two coherent fields impinging simultaneously on the wafer and creating a coherent superposition. The obvious example is interferometric systems [10, 11].

The concept presented in this patent differs because it is an example of Multifield incoherent lithography using two fields derived from the same master and does not required coherent light.

Registration:

The main issue in multifield incoherent—and coherent—lithography is registration. Indeed, if the optical paths are different, the slight OPD differences, due to lens and systems variations and imperfections will create, at the level of precision required in modern lithography, uncorrectable errors. In coherent multifield aerial image, i.e. Interferometric Lithography, this issue has been dealt with by removing any information on one of the beams, the reference beam. Because of this, any position on the beam is equivalent to another one, relaxing the superposition constraints of one beam relative to the other. In Incoherent Multifield aerial image, I avoid the problem by having the two beams propagating either exactly along the same path, with different polarizations, or with paths displaced one from the other by a small amount, laterally or longitudinally, below a single wavelength. Under this assumption, the two optical paths are fully equivalent and any modification of one of them is fully mirrored on the other one, in a way, which can be compared to differential transmission in electrical systems.

I define now the concept of multifield aerial image. The multifield aerial image is the coherent superposition of two—or more—optical fields, these fields being derived from a single mask; each field is a modified replica of the original field, the master. A replica is a duplicate of the master on which a simple operator—as for example a translation or defocusing—had been applied.

To clarify our terminology, we will use the term of master for the field which will have been created by the system without the addition of the optical means described below. A more accurate definition is presented in a following paragraph. A duplicate is a field with potentially lower energy, identical to the master; a modified replica or replica in short, for a field, different from the master, on which a simple operator has been applied.

The multifield aerial image shape is different depending on the splitting amplitude ratio, the ratio of energy between the first and second fields. It varies from being identical with the first field, if the splitting amplitude ratio is 1, to be identical to the second field when this ratio is 0. However, the transition is highly non-linear due to the quadratic dependence of the optical intensity. As an example, for a splitting ratio of 0.5 or close to it, for a modified replica being a defocused version of the master, the multifield is a high-pass filtered version of the master, yielding the surprising effect of resolution tripling. Because of this, several different independent multifield aerial images can be created by varying the splitting amplitude ratio.

The exposure multifield aerial image is the weighted superposition of several independent multifield aerial images. It can be obtained using the same mask and optical set-up, in a single optical exposure, through a modification of the splitting ratio.

Up to this point, no explanation or description had been presented to describe the implementation of the physical mechanisms able to perform the functional modification of the fields as described. I implement this method by using Nomarski Lithography, NL. It provides an additional optical step, in which the initial optical field, created by the mask is modified by an additional optical module.

NL provides additional domains of parametrization, in addition to the existing ones, opening the way to either increasing the definition and complexity of aerial images, increasing the process window, decreasing the complexity of the masks or combining all three functions.

In this patent I will use several additional terms and concepts defined here.

Birefringent Lithography is a generic name I propose for the family of multifield incoherent lithographic techniques based on birefringence. These techniques are based on the use of uniaxial crystals and polarization optics modules as tools to duplicate, modify and densify aerial images. Crystal modules have indeed the ability to duplicate a master beam into a number of replicas with predetermined variations. These replicas are coherent with the master beam and totally registered to it.

Nomarski Lithography is a superset of birefringent lithography including additional techniques—as the use of gratings—to perform optically the creation of modified replicas.

I named this approach to Lithography, Nomarski Lithography, in honor to a great scientist and due to some basic conceptual similarity to Nomarski Differential Intensity Contrast microscopy [12-14]. Nomarski Differential Intensity Contrast Microscopy is a technique invented in 1953 by George Nomarski. The technique is well documented in the literature [15] or in the original papers [13, 14, 16-19] and in the original patent [12] of Georges Nomarski. In short, in a standard microscope set-up, before the objective, a Wollaston prism is positioned (see for example FIG. 29.2 of [20]). The illumination and the returned light passes through the Wollaston prism in order to create two slightly displaced beams, with orthogonal polarizations. Upon reflection from the sample, the beam returns through the objective and come together as they exit the Wollaston.

Nomarski Lithography—referred as NL in this patent—provides the ability to densify an aerial image. The idea to densify optical pattern exists in the early literature, through the Talbot and Montgomery fractional effects [4, 5]. However, the Talbot and Montgomery effects are able to densify only periodic or quasi-periodic patterns. NL is adapted to local arbitrary features and does not rely on periodicity; it can be performed either between two isolated lines or for a dense pattern. In short, NL may permit the use of simple, lower cost masks to access the higher nodes of Moore law.

As an example of possible densification of an image, to illustrate the more general concept, I will describe density tripling; I will show preliminary simulations, for a phase mask with a 195 nm line separation (half-pitch), which will create an aerial image of 65 nm half-pitch.

It can be appreciated that optical lithography has been in use for years. Typically, optical lithography imaging refers to all the standard aerial image creation techniques for lithography of semiconductors. I will not review the theory of image formation in Lithography, which is analyzed and reviewed yearly in depth by the ITRS in its annual reports and through their well-known roadmap, which may be found at http://public.itrs.net/. Another source of information for the specialist is the SPIE proceedings and the JM3 journal—the Journal of Microlithography, Microfabrication and Microsystems.

Optical Resolution:

The main problem with conventional optical lithography are obviously that the resolution of modern lithographic equipment is below the limit of diffraction and very complex set-ups have to be used and are developed to reach thinner and thinner features on the wafer in order to continue to follow the pace of the Moore's law.

Single Optical Field:

Another problem with conventional optical lithography is that most techniques are based on a single optical field paradigm, in which the aerial image is created using a single optical field. Most systems used a mask, imaged using a dedicated optical imaging system. Dual optical fields added incoherently and sequentially have been proposed and are recognized as one of the potential path towards the 32 nm node. However, all these techniques are based on sequential addition of two or more intensities.

Interferometric methods have also been proposed—as for example by Brueck [10, 11] and his team, in which a coherent uniform reference beam interfere with the light distribution. A dual incoherent field superposition using birefringent media, has also been proposed—in order to increase the depth of focus by Kim [21].

While these devices may be suitable for the particular purpose to which they address, they are not as suitable for develop a new approach to optical Lithography enabling the creation of more complex and more resolved light distribution using simpler masks.

In these respects, the Multifield Incoherent Lithography according to the present invention substantially departs from the conventional concepts and designs of the prior art, and in so doing provides an apparatus primarily developed for the purpose of develop a new approach to optical Lithography enabling the creation of more complex and more resolved light distribution using simpler masks.

The master field is the field created by the system without the Nomarski Lithography system. To be more accurate, the master field, for birefringent lithography, is the field created by the system if all birefringent elements are replaced by isotropic element with index of refraction equal to the ordinary index of refraction of the birefringent element.

Equivalent Mask:

I introduce also the concept of the equivalent mask. The equivalent mask is the physical mask, which will have created the same multifield field, without Nomarski Lithography. The equivalent mask is a mathematical construction and does not need to be a physically realizable mask. Unlike a binary or phase mask, it is parameterized by the energy ratio between the master and the replica. The equivalent mask is calculated by inverting the transfer function of the lens. The algorithms for retrieving a mask from the aerial image are reviewed in several papers as for example, by Y. Granik [6].

### SUMMARY OF INVENTION

In view of the foregoing disadvantages inherent in the known types of optical lithography now present in the prior art, the present invention provides a new Multifield aerial image construction wherein the same can be utilized for develop a new approach to optical Lithography enabling the creation of more complex and more resolved light distribution using simpler masks.

The general purpose of the present invention, which will be described subsequently in greater detail, is to provide a new Multifield Incoherent Lithography that has many of the advantages of the optical lithography mentioned heretofore and many novel features that result in a new Multifield Incoherent Lithography which is not anticipated, rendered obvious, suggested, or even implied by any of the prior art single field optical lithography, Multifield Coherent Lithography or Multiple Exposure Lithography either alone or in any combination thereof.

The essence of Multifield Incoherent Lithography can be understood through the three following constitutive mathematical equations and drawing 1, the schematic description of the system:

$$\begin{matrix}{E}_{comp}^{i} ( x , y ) = {α}_{i} {\tilde{F}}_{1} ( {E}_{Master } ( x , y ) ) + {β}_{i} {\tilde{F}}_{2} ( {E}_{Master} ( x , y ) ) & ( 1 ) \\ {I}_{comp}^{i} ( x , y ) = {E}_{comp}^{i} ( x , y ) conjg ( {E}_{comp}^{i} ( x , y ) ) & ( 2 ) \\ {I}_{comp} ( x , y ) = {\sum }_{i} {I}_{comp}^{i} ( x , y ) & ( 3 )\end{matrix}$$

Let a mask be illuminated by an appropriate illumination system and imaged using a suitable imaging system. The combination of all the lithographic hardware will be referred to, as the lithographic equipment. The aerial image created by it is the master.

We first create two—or more—identical duplicates of the master field using the separator. The two fields are totally coherent and fully registered, but propagate separately, as two independent fields, in two different optical states. The fields may be differentiated for example by their polarization state or by their position or by another physical parameter. The energy ratio between the two duplicates can be fixed, or controllable, either statically or dynamically

We then apply, on each field separately, a modification, represented by a mathematical operator F_{1,2}; in many cases, the operator, for the first field will be an identity operator and we will refer to this field also, for simplicity, as the master. The other field(s) will be referring to as replica(s). This operation, performed simultaneously, by the same optical component, the differentiator, on both duplicates.

To make the two fields interfere we use a combiner, which put them back in the same optical state. The energy efficiency of the translation of the two duplications to the final state can be fixed, or controllable, either statically or dynamically

The final result is the combined field, corresponding to the coherent interference of the two fields and represented mathematically by Eⁱ_{comb} and calculated by equation (1). Its energy is represented by Iⁱ_{comp}, as presented in equation (2)

In some embodiments of this invention, several different variations of the multifield field intensity will be realized sequentially, creating an overall energy exposure, I_{TOTAL}, represented in equation (3).

A major component of the system is the algorithm. The problem of mask optimization and mask source optimization have been described in several papers [5-8]. The addition of an additional parameter domain, which provides additional optimization capacity of a different domain, can be performed, either by integral techniques, i.e. by optimizing all parameters together, or by optimizing sequentially the source/mask/coherence parameters with a fixed set of multifield parameters and optimizing the multifield/mask parameter using fixed source and coherence parameters. It is clear that the solution to create an exposure multifield aerial image spans a larger domain of solutions, and so inherently better solutions in the sense of the optimization parameters, at the cost of additional hardware and modelization complexities.

There has thus been outlined, rather broadly, the more important features of the invention in order that the detailed description thereof may be better understood, and in order that the present contribution to the art may be better appreciated. There are additional features of the invention that will be described hereinafter.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

A primary object of the present invention is to provide a Multifield Incoherent Lithography that creates a multiple optical field imaging, using incoherent or partially coherent illumination, in which the final optical intensity is the coherent combination, at each position, of several replicas of the original field; the replicas are coherent with the master field even if the illumination is incoherent because they are derived from it point by point. The replica are differentiated from the master by a primary modification, whether this modification can be of any type, as for example, a lateral or longitudinal displacement or a slight defocusing.

Another object is to provide a Multifield aerial image that creates a multifield optical exposure made of a plurality of fields. The exposure is obtained without changing the relative position of the original mask and the wafer. The different fields being created from the coherent combination of replica as described above, the different fields being differentiated using a dynamic parameter, controllable during the exposure.

Another object is to provide a multifield aerial image that allows the optimization of the process in order to calculate the mask and the dynamic parameters values to be used to create a predetermined aerial image on the wafer.

Another object is to provide a multifield aerial image to create the said replicas using uniaxial crystals plates, Wollaston or Rochon prisms, or similar uniaxial-based elements.

Another object is to provide a multifield aerial image to realize resolution tripling using superposition of two coherent registered fields.

Other objects and advantages of the present invention will become obvious to the reader and it is intended that these objects and advantages are within the scope of the present invention.

To the accomplishment of the above and related objects, this invention may be embodied in the form illustrated in the accompanying drawings, attention being called to the fact, however, that the drawings are illustrative only, and that changes may be made in the specific construction illustrated.

### BRIEF DESCRIPTION OF THE DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

FIG. 1 represents schematically the concept of the multifield Incoherent aerial image

FIG. 2 is a graphical drawing of a lithographic system without—FIG. 2a—and with—FIG. 2b—a Nomarski Lithography module

FIG. 3 is a description of the behavior of the system with and without density tripling.

FIG. 4 is a description of the behavior of the system with and without density tripling in the Fourier domain.

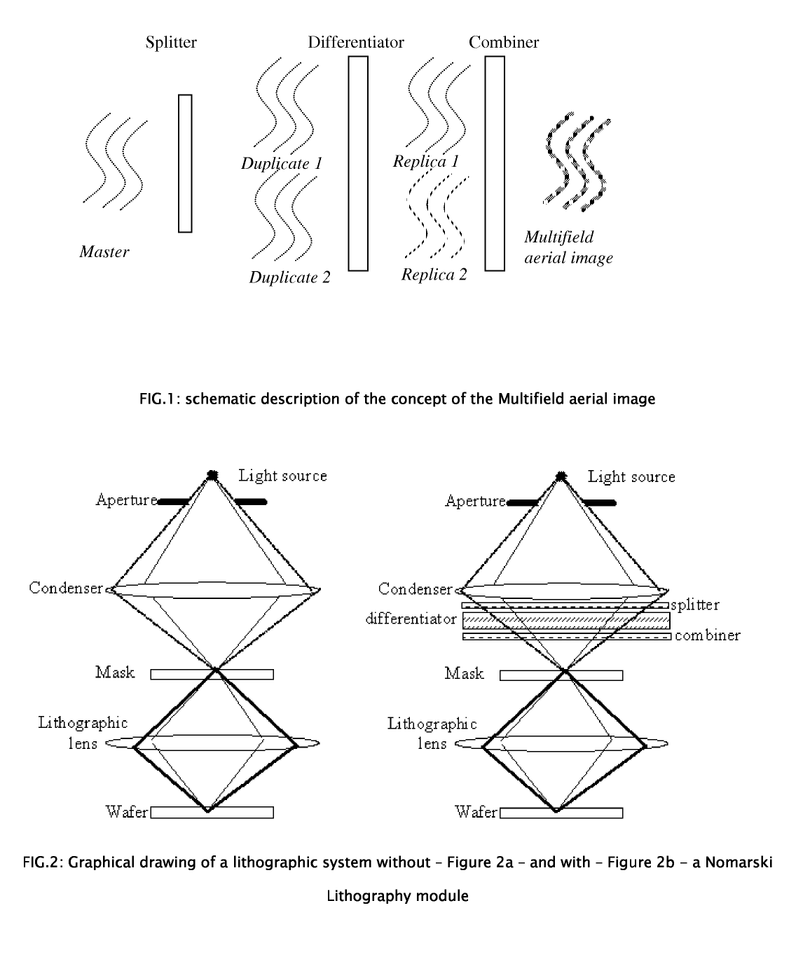

### DETAILED DESCRIPTION OF THE INVENTION

Turning now descriptively to the drawings, in which similar reference characters denote similar elements throughout the several views, the attached figures illustrate a Nomarski lithography system, which comprises an optical lithography system, a separator, a differentiator, a combiner and mathematical algorithms.

To attain this, the present invention generally comprises an optical lithography system, a separator, a differentiator, a combiner and mathematical algorithms. In this section we will describe in more details the function of each of the modules of the system, which functionality have been sketchily presented in the previous section.

Optical lithography system—is a standard or custom modified optical lithographic system able to image with high fidelity a mask on a wafer. The main manufacturers of such systems are ASML, Nikon and Canon.

Separator—the separator creates two duplicates of the master. As a descriptive example, a birefringent crystal separates the incoming light into two modes, an ordinary and an extraordinary mode.

Differentiator—The differentiator adds, selectively, a predetermined OPD—optical Path Difference, different for both duplicates. In the cases, that for one of the duplicates, the operator applied is a unity operator we will continue to refer to this duplicate as a master.

Combiner—The combiner put the master and the replica—or the replicas—into the same optical state to make them interfere. In the case that the two fields were carried by different polarizations the combiner is an analyzer.

Mathematical algorithms—The mathematical algorithm permits to calculate the original mask and the parameters of the multifield field or fields to create a predetermined aerial image.

One of the assets of Nomarski Lithography is the capacity to use Sapphire, the transparent material with the highest index of refraction in the UV. The ordinary and extraordinary indices of refraction of Sapphire at 193 nm, are nₒ=1.9288 and nₑ=1.9174. The birefringence, Δn, is negative and equal to −0.0114.

The aim of the system is to create two fields, with a predetermined differentiation between them, coherent one to the other on a point by point basis. Several solutions can be proposed for this function; the simplest ones use birefringent or polarized based solutions, although this patent applies to all potential implementations. A non-exclusive list will be presented at the end of this paragraph. I will first review the different variations of the invention in which the differentiator is a single crystal plate, but I will continue the description depicting one case—the simplest one—of a birefringent plate with axis parallel to the geometrical optical axis, referred in this patent as the defocus NL.

Alternative Variations of the Invention Using a Single Optical Plate:

For a single crystal parallel plate, three simple generic cases exist, depending on the relative angles between the geometrical axis of the system and the crystal optical axis.

Lateral NL:

In the first configuration, double refraction configuration, the geometrical axis of the system and the optical crystal axis make an angle of 45 degrees one relative to the other. This configuration creates a maximal lateral shift between the ordinary and extraordinary images. The extraordinary ray creates a laterally shifted replica. This is inherently a double refraction case or birefringent translator, which picturesque illustration can be found in many venerable optics books labeled as Iceland spar. The module creates, for the chief ray, a lateral translation of the extraordinary ray relative to the ordinary one. However, besides the lateral translation, additional effects are created in the extraordinary mode due to the angular dependence of the extraordinary index of refraction. This dependence, known as a birefringent aberration, is similar to the formalism described, for example, by Unno [8], for a rotationally symmetric birefringent lens. It creates an angle dependant variation of the OPD for the replica. In short, it suffers from large aberrations in the extraordinary mode will not behave properly in actual cases of lithography. The possible modification of the reduction factor of lithographic equipment from a magnification of 4 to a magnification of 8 may markedly change this situation. Although the consensus of lithographic experts [19] is—at this point of time, end of 2005-against such a modification of the existing concepts, this issue may still evolve in the future. With a reduction factor of 8 the NA—at the mask side—will be reduced to values below 0.15, even for future hyperlens with NA of 1.2. Taking into account the Sapphire high (ordinary) index of refraction at 193 nm, no=1.93, the angles inside the crystal will be below 4.6 degrees around the geometrical axis and the aberrations may be manageable.

Longitudinal NL:

In the second configuration, the geometrical axis of the system and the optical crystal axis are perpendicular. This configuration will not be detailed in this patent, because the defocus NL, described in the next paragraph, creates a similar effect, with—potentially—better performances. This configuration functionality can be described as a birefringent defocus. It has some similarities, without the additional polarizer, to the set-up used for focusing improvement in reference [18]. In reference [18], the two orthogonal polarizations, slightly defocused one relatively to the other, are utilized to increase the depth of focus, using incoherent superposition of the two fields.

Defocus NL:

In the last case, the geometrical axis of the system and the optical crystal axis are parallel. This configuration functionality can also be described as a birefringent defocus. The chief ray will propagate the same way in the ordinary and extraordinary modes. The exactly same aberrations we were trying to avoid in all optical lithography will be the basis of the defocusing of the extraordinary wave of NL. The set-up is fully rotationally symmetric, yielding a very simple, unaberrated effect. An additional advantage of defocused NL is due to the fact that the ordinary and extraordinary modes are circularly polarized modes. The analyzer includes a quarter wave plate and a linear polarizer. The final linear polarizer can be adjusted at any angle, statically or dynamically, permitting to switch the TE mode to be parallel to the dense pattern direction.

Defocus Field Calculation for on-Axis Illumination:

The overall defocus is a complex addition of two effects. The first effect, known as the double refraction effect, is due to the discrepancy between the Poynting vector angle—the direction of the flow of energy—and the ray-optic angle in the crystal, used in Snell's law. The second effect is the addition of an angle dependant phase for rays traveling at angle different from the optical axis of the crystal. This effect is due to the angular dependence of the extraordinary index of refraction. Both effects cancel in the direction of the optical axis of the crystal, which have been chosen as the optical axis of the system. Both effects do not have an azimuthal dependence and scale linearly with the crystal thickness. The first effect creates a translation of off-axis rays whether the second effect creates an overall defocusing of the wave. The theoretical framework of these effects can be found in several references as [22-25]. Defocus calculation as function of crystal thickness can be calculated either analytically or using commercial simulation programs. A complete model is not necessary in the simplest case of on-axis illumination, because both effects behave the same way, an isotropic blurring of the point by an amount determined by the crystal thickness. In short, the defocus is a monotonic function of the crystal thickness, independent of the azimuth of the ray and going to zero for zero thickness, with a linear region close to this zero value. In the following simulations we use a simple cosine model of the defocusing field.

Defocus Field Calculation for Off-Axis Illumination:

The off-axis illumination is the real case used in lithography. It has to be noted that illumination in lithography are designed to be fully symmetric relative to the orthogonal axes of the system. The reason is that any slight asymmetry creates a decenter which strongly impair the performance of the system for a slight defocus, reducing markedly the processing window. This constraint is so tight that some algorithms take it as a prerequisite in calculation of fields as function of the illumination parameters. They deal only with one quadrant, in the illumination domain, taking for granted the symmetry of the other quadrants and reducing accordingly the calculation load. The defocus calculation as function of crystal thickness is even more complex and can be simulated using commercial simulation programs. Under the symmetry condition, the defocus is a monotonic function of the crystal thickness, going to zero for zero thickness, with a linear region close to this zero value. For annular illumination, the independence of azimuthal angle is kept, simplifying the overall calculations. On the other hand, for other illumination schemes a slight coupling exists between the defocus and the illumination shape. It makes the calculation more complex on one side, but provides a small additional mechanism of variation of parameters. It may be translated to a better optimization of the system by giving additional dependence and variability.

Imaging and Machine Vision:

The described method was drawn in the context of masks and lithography; it can be applied to any imaging system without major changes. The use of this method, the creation of a multifield incoherent—or partially coherent—aerial image on the basis of a master field, for different imaging applications is indeed claimed as part of this patent.

As a simple example, for machine vision applications, the use of the same set-up described below for density tripling, will emphasize optically the high frequency contents of an image; for defect analysis it will emphasize the defect and reduce the energy content of the background yielding a better selectivity of small defects.

In short, any imaging or machine vision application using this method to improve an aerial image in the sense that imaged features are recorded or detected in a more efficient way will be recognized as part of this patent.

We will now describe in more details the physical components able to create the three functionalities necessitated by the three components: the splitter, the differentiator and the combiner.

For a system based on polarized light the splitter is quite naturally implemented using any version of polarizers. Many types of polarizers are available and are known to the person skilled in art. A full review is not needed to be presented here and can be found in many well-known publications as for example the Handbook of Optics published by the Optical Society of America.

For a system based on polarized light the differentiator can be implemented using single crystal plates—as described in this paper—using Wollaston and Rochon prisms—in a way similar to Nomarski Microscopy or using any component able to modify differently and selectively the fields carried by the two polarizations.

For a system based on polarized light the combiner is an analyzer. The analyzer is a polarizer and can be implemented using any type of polarizers as described in a previous paragraph.

For a system based on geometrical separation the splitter and combiner can be based on any component able to separate the light into two—or more—duplicates of the incident field, as beamsplitters, polarizing and non-polarizing, gratings, Fabry-Perot or any optical component performing the said functionality.

For a system based on geometrical separation the differentiation maybe implemented naturally by the creation of a natural optical path difference due to the geometrical differences between the fields.

It has to be mentioned that polarization and geometrical separation are not incompatible and systems can be built, which incorporate components performing either one or both functionalities.

As to a further discussion of the manner of usage and operation of the present invention, the same should be apparent from the above description. Accordingly, no further discussion relating to the manner of usage and operation will be provided.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

The embodiment described in the following paragraph is the simplest and one of the most valuable embodiments of this patent. However, many other embodiments can be inferred from the general methodology described here. We will refer to this specific embodiment as density tripling.

Density Tripling:

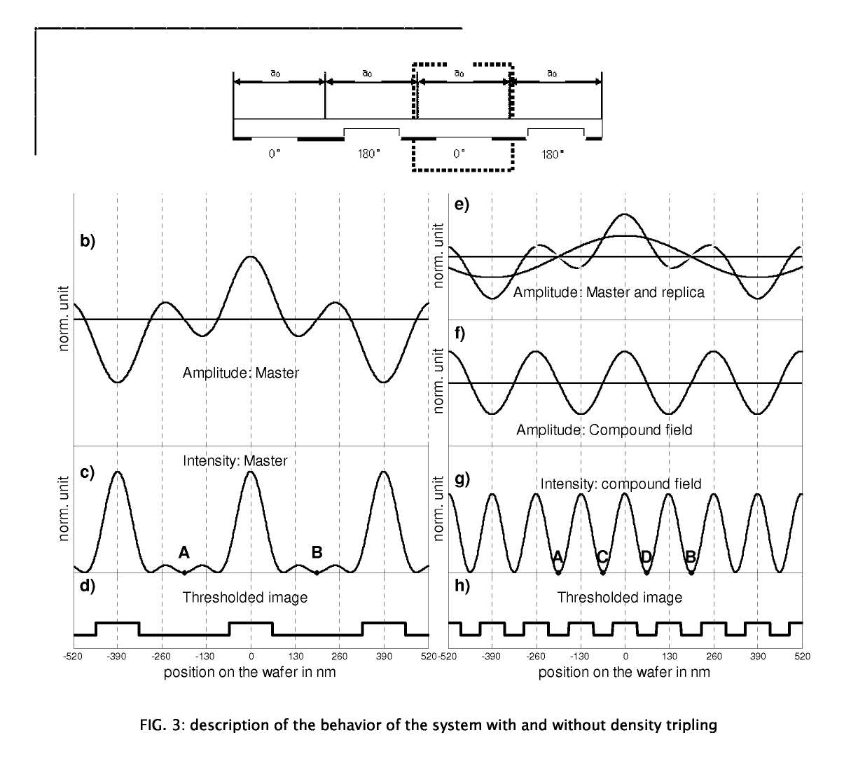

Density tripling is illustrated schematically in FIG. 3. The illumination is polarized at a defined polarized state—linear or circular. An amplitude or phase mask of a pattern made of lines, in the figure, or another motif of lower density is positioned in the system.

After the mask, the light is separated in two channels, using polarization effects. One of the channels is unmodified, and will be referred to as the master. The other channel will be referred to as the replica. On this channel a predetermined modification has been applied; the replica is fully coherent and registered to the master image but polarized at an orthogonal polarization to it. A controlled variation is applied on the replica, relative to the master, in the case of On Line Nomarski Lithography, defocusing by a fixed amount. The final optical field is created by the coherent superposition of the two—or more—fields, even for incoherent or partially coherent illumination. To make the master and replica interfere destructively an analyzer is placed in the optical path. The analyzer is placed at an intermediate polarization state between polarization state of the master and the replica, creating a destructive interference.

FIG. 3 describes the behavior of the system with and without density tripling. The model we use for the defocused field is a cosine model which we assume to gave an acceptable description of the blurred point. A more accurate calculation of the exact defocusing shape, taking into account the combination of the two birefringent effects and the specific lens will be necessary to be done on a practical case. FIG. 3a presents first the mask used for creating the original field. The original field amplitude, FIG. 3b, and its intensity, FIG. 3c are represented, as well as the pattern, in FIG. 3d, created by applying a simple threshold to the master field. FIG. 3e represents the master field and the replica; for illustration purpose the negative of the replica is also drawn. As said, the replica is a slightly defocus version of the point, modeled in this case as a simple cosine function. FIG. 3f represents the compound field obtained by creating coherent superposition of the master field and the replica. FIG. 3g represents the intensity of the compound field. The threshold pattern is represented in FIG. 3h. In FIG. 3g, the intensity passes through zero at the position corresponding to the two original lines (points A and B) and creates two dark lines at these positions, as is doing the master field alone FIG. 3c. It will also passes through two additional amplitude zeros inside the cell, due to different shapes of the two elementary fields. Overall, this system creates two additional lines between the original ones, effectively tripling the line density.

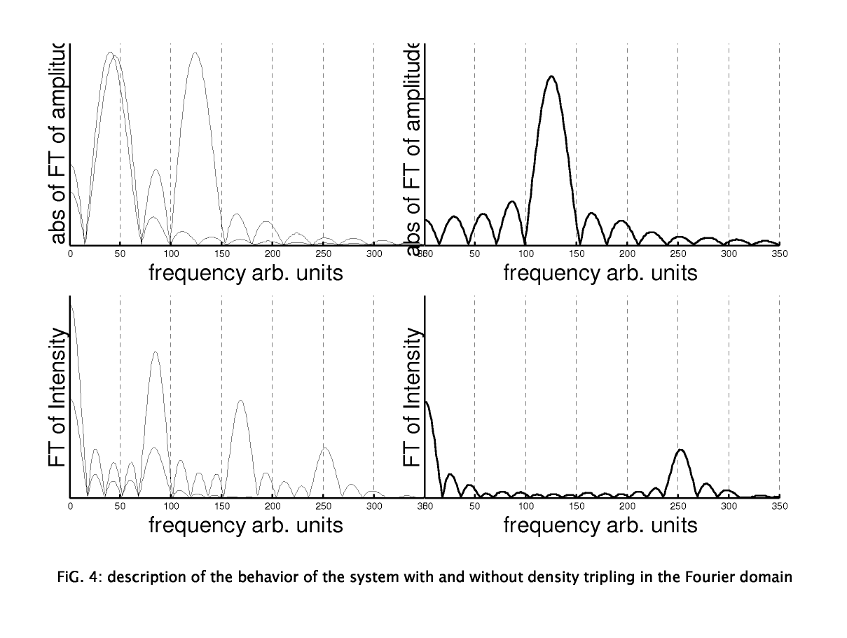

The explanation of this apparently strange behavior is made clear in the Fourier Transform domain. We choose the term of density tripling for this technology, although the term “third harmonics lithography” may have been as appropriate (FIG. 4). The master field contains a first and second harmonics in its amplitude (FIG. 4a) and because of this, a third harmonics in its intensity (FIG. 4b). The replica contains only the first harmonics in its amplitude. The compound field, created by the subtraction of the master and replica removes, in the intensity the first and second harmonics (FIG. 4a and FIG. 4b). It leaves only the third harmonics. The third harmonic does not appear ad nihilo; the mask pattern chosen has a finite amount of second order of diffraction in the amplitude and, because of this, a third order of diffraction in the intensity.

Fourier domain filtering is not available for incoherent or partially coherent light. Because of this we choose to subtract the first harmonics in amplitude using a brut force solution, subtracting it by adding a second field, coherent with the first one, with a phase difference of 180°. The system reduces to zero the first harmonics of the amplitude, and so the first and second harmonics of the intensity, through the subtraction of the replica. The compound field, which includes only the third harmonics, is equivalent to the field which will have been created with a mask with three times more density.

Density tripling can be made isotropic in the plane. It works equally well for x or y patterns in the same exposure, although it is not prone to polarization effects for high Numerical Aperture as is the case of any lithographic system.

The polarization angle of the input polarization state is controlled, statically or dynamically. This control permits to adjust the balance of intensity between the master and the replica.
1. Balasinski, A., Optimization of sub-700-nm designs for mask cost reduction. Journal Of Microlithography Microfabrication And Microsystems, 2004. 3(2): p. 322-331.
2. Fritze, M. and B. Tyrrell, Prospects and challenges of optical RET. Solid State Technology, 2003. 46(2): p. 61-+.
3. ITRS, International Technological Map for Semiconductor 2004, Lithography update. 2004, ITRS. p. 1-22.
4. Levenson, M. D., N. S. Viswanathan, and R. A. Simpson, Improving Resolution In Photolithography With A Phase-Shifting Mask. IEEE Transactions On Electron Devices, 1982.29(12): p. 1828-1836.
5. Rosenbluth, A., E., et al. Optimum mask and source patterns to print a given shape. 2001: SPIE.
6. Granik, Y., Source optimization for image fidelity and throughput. Journal of Microlithography, Microfabrication, and Microsystems, 2004. 3(4): p. 509-522.
7. Granik, Y. Solving inverse problems of optical microlithography. 2004: SHE.
8. Socha, R., j., et al. Contact hole reticle optimization by using interference mapping lithography (IML). 2004: SPIE.
9. Schellenberg, F. M., A history of resolution enhancement technology. Optical Review, 2005. 12(2): p. 83-89.
10. Chen, X. L. and S. R. J. Brueck, Experimental comparison of off-axis illumination and imaging interferometric lithography. Journal Of Vacuum Science & Technology B, 1999. 17(3): p. 921-929.
11. Frauenglass, A., et al., 244-nm imaging interferometric lithography. Journal Of Vacuum Science & Technology B, 2004. 22(6): p. 3465-3469.
12. Nomarski, G., INPI, Editor. 1952.
13. Nomarski, G., Nouveau Dispositif Pour Lobservation En Contraste De Phase Differentiel. Journal De Physique Et Le Radium, 1955. 16: p. S88-S88.
14. Francon, M. and G. Nomarski, Dispositif A Contraste De Phase Independant Du Microscope Et Utilisant Une Lame De Phase A Absorption Variable. Comptes Rendus Hebdomadaires Des Seances De L Academie Des Sciences, 1950. 230(11): p. 1050-1051.
15. Mansuripur, M., Classical optics and its applications. 2002, Cambridge, UK; New York, N.Y.: Cambridge University Press. ix, 502 p.
16. Nomarski, G., Double-Shear Differential Interferometer Using Birefringent Beamsplitter. Japanese Journal Of Applied Physics, 1975. 14: p. 363-368.
17. Nomarski, G., Use Of A Weak Birefringent Lens For Spatial Filtering. Journal Of The Optical Society Of America, 1972. 62(11): p. 1392-1392.
18. Nomarski, G., Comparison Of Methods Of Phase-Object Visualization-Small Shear Interference Ssi), Phase Grating Schlieren (Pgs), And Wolters Minimum Schlieren (Wms). Journal Of The Optical Society Of America, 1970. 60(5): p. 740-&.
19. Nomarski, G., Interference Microscopy—State Of Art And Its Future. Journal Of The Optical Society Of America, 1970. 60(11): p. 1575-&.
20. Mansuripur, Classical optics and its applications. 2002, Cambridge: Cambridge University Press.
21. Kim, D., et al. New technology for enhancing depth of focus using birefringent material. 1999: SPIE.
22. Born, M. and E. Wolf, Principles of optics: electromagnetic theory of propagation, interference and diffraction of light. 6th (corr.) ed. 1997, Cambridge, UK; New York: Cambridge University Press. xxviii, 808 p.
23. Yariv, A. and P. Yeh, Optical waves in crystals: propagation and control of laser radiation. Wiley classics library ed. 2003, Hoboken, N.J.: John Wiley and Sons. xi, 589 p.
24. Sirat, G. Y., Conoscopic Holography.2. Rigorous Derivation. Journal of the Optical Society of America a-Optics Image Science and Vision, 1992. 9(1): p. 84-90.
25. Sirat, G. Y., Conoscopic Holography.1. Basic Principles and Physical Basis. Journal of the Optical Society of America a-Optics Image Science and Vision, 1992. 9(1): p. 70-83.

What is claimed is:

1. A method for creating an optical light intensity distribution using either a mask and a lithographic system or an imaging or machine vision systems, either one being illuminated by incoherent or partially coherent illumination. The method includes a generic step, the creation of the multifield aerial image. It is realized by performing the following physical functions on the optical field:
Splitter: Splitting the light in two—or more—fields identical to the original field,
Differentiator: Creating a modification, of one—or more—of the duplicate fields,
Combiner: Putting the fields back into the same optical state, to make them interfere.
The resulting optical field intensity, named the multifield aerial image, is the coherent superposition of the two—or more—final fields, even with incoherent or partially coherent illumination.

2. An apparatus for realizing the splitter of the method described in claim 1, whether the initial light is polarized and splitting is performed into two different optical fields with different polarizations; the apparatus can use any known polarizing means, including but not limited to, polarizers, polarizing beamsplitters, Rochon and Wollaston prisms, polarizing translators, uniaxial plates, wedges or lenses.

3. An apparatus for realizing the splitter of the method described in claim 1, whether the initial light is polarized or unpolarized and splitting is performed into two different optical fields with slightly different geometrical characteristics, either angular or translatory; the apparatus can use any known geometrical splitting means, including but not limited to, gratings, polarizing and non-polarizing beamsplitters, Rochon and Wollaston prisms, polarizing and non-polarizing translators.

4. An apparatus for realizing the differentiator of the method described in claim 1, whether the initial light was polarized and the splitting has been performed into two different optical fields with different polarizations; the apparatus can use any known polarizing modification means, including but not limited to, Rochon and Wollaston prisms, polarizing translators, uniaxial plates, wedges or lenses or electrooptic modulators.

5. An apparatus for realizing the differentiator of the method described in claim 1, whether the differentiation between the two beams includes but is not limited to a lateral or longitudinal translation or a defocus.

6. An apparatus for realizing the differentiator of the method described in claim 1, whether the initial light is polarized or unpolarized and splitting has been performed into two different optical fields with slightly different geometrical characteristics, either angular or translatory; the apparatus will be based on the slight difference of optical path due to the spatial differentiation of the two beams.

7. An apparatus for realizing the combiner of the method described in claim 1, whether the initial light was polarized and splitting has been performed into two different optical fields with different polarizations; the apparatus can use any known polarizing means, including but not limited to, polarizers, polarizing beamsplitters, Rochon and Wollaston prisms, polarizing translators, uniaxial plates, wedges or lenses.

8. An apparatus for realizing the combiner of the method described in claim 1, whether the initial light was polarized or unpolarized and splitting has been performed into two different optical fields with slightly different geometrical characteristics, either angular or translatory; the apparatus can use any known geometrical combining means, including but not limited to, gratings, polarizing and non-polarizing beamsplitters, Rochon and Wollaston prisms, polarizing and non-polarizing translators.

9. A system for realizing the method described in claim 1 whether all the additional components are placed either between the mask and the lithographic lens or whether some components are placed between the lens and the wafer.

10. A system for realizing the method described in claim 1 whether the components use the uniaxial properties of a Sapphire, KDP or Quartz crystal at 193 nm or any of the available uniaxial crystals in the visible.

11. A system for realizing the method described in claim 1 whether the polarization states after the splitter are linear, circular, elliptic or radial polarizations.

12. A method as described in claim 1, whether the system is used for lithography of semiconductors

13. A method as described in claim 1, whether the system is used for imaging and machine vision

14. A method for creating an optical light intensity distribution using a mask and a lithographic system illuminated by incoherent or partially coherent illumination. The method includes realizing sequentially, one time or more, with different overall accumulated energy, several independent multifield aerial images described in claim 1. The multifield aerial images are differentiated one from the other by modifying dynamically the energy ratio between the two final fields. The overall light energy is referred to as the exposure multifield aerial image.

15. An apparatus for modifying the relative amplitude of the two final optical fields of the method described in claim 14 whether the initial light was polarized and splitting has been performed into two different optical fields with different polarizations; the apparatus can use any known polarization modifier on either the splitter or the combiner, including but not limited to mechanical movement of the polarization components, electro-, acousto- or magneto-optic effects.

16. An apparatus for modifying the relative amplitude of the two final optical fields of the method described in claim 14 whether the initial light was polarized or unpolarized and splitting has been performed into two different optical fields with slightly different geometrical characteristics, either angular or translatory; the apparatus can use any known geometrical modifier on either the splitter or the combiner, including but not limited to mechanical movement of the components.

17. A method of calculation for retrieving the initial mask from the multifield aerial image of the method described in claim 1, by first retrieving the master field from the multifield aerial image by any known inverse methods able of inverting numerically the operators applied on the master field and then using any of the available algorithms for retrieving a mask from its aerial image.

18. A method of calculation for retrieving the initial mask from the multifield aerial image of the method described in claim 1, by first using any of the available algorithms for retrieving a mask from its aerial image to calculate the equivalent mask and then calculating the initial mask from the equivalent mask.

19. A method of calculation for optimizing the initial mask to reach the exposure multifield aerial image of the method described in claim 14, by using any of the available algorithms to calculate the master field from the initial mask, calculating the exposure multifield aerial image from the master field using a given set of parameters and applying any of the known mathematical optimization procedures—either global or local—to reach a target exposure multifield aerial image.

20. A method of calculation for optimizing the initial mask to reach the exposure multifield aerial image of the method described in claim 14, by using any of the available algorithms to calculate first the equivalent mask from the exposure multifield aerial image. A second step of calculating the initial mask from the equivalent mask can be performed whether a set of rules can be defined to realize this transformation.
